(19) United States
(12) Patent Application Publication
(10) Pub. No.: US 2026/0311774 A1
(43) Pub. Date: Oct. 8, 2026

(54) MEMORY DEVICE, OPERATING METHOD THEREOF, AND MEMORY SYSTEM

(71) Applicant: YANGTZE MEMORY TECHNOLOGIES CO., LTD., Wuhan (CN)

(72) Inventor: Fang XU, Wuhan (CN)

(21) Appl. No.: 19/286,979

(22) Filed: Jul. 31, 2025

(30) Foreign Application Priority Data
Apr. 7, 2025 (CN) 2025104310166

(51) Int. Cl. G11C 16/28; G11C 16/04

(52) U.S. Cl. CPC G11C 16/28; G11C 16/0483

(57) ABSTRACT

A memory device includes a memory array and a peripheral circuit coupled to the memory array and configured to: perform a first detection operation on a plurality of memory cells in the memory array and coupled to a target word line to obtain a first detection result, wherein the first detection operation comprises a plurality of read phases, read voltages with different magnitudes are applied to the target word line in different read phases, and the first detection result comprises detection states of the plurality of read phases; and perform a second detection operation on the plurality of memory cells based on the first detection result, wherein a number of read phases comprised in the second detection operation is obtained based on the detection states of the plurality of read phases.

### CROSS-REFERENCE TO RELATED APPLICATIONS

The present disclosure claims priority to Chinese Patent Application No. 2025104310166, which was filed Apr. 7, 2025, and is hereby incorporated herein by reference in its entirety.

### TECHNICAL FIELD

The present disclosure relates to the field of semiconductor technologies, and in particular, to a memory device, an operating method thereof, and a memory system.

### BACKGROUND

Memory devices are storage devices in modern information technology for storing information. As a typical non-volatile semiconductor memory, NAND (Not-And) type memories gradually become mainstream products in the storage market due to high storage density, controllable production cost, and suitable program and erase speed.

### SUMMARY

In view of this, examples of the present disclosure provide a memory device, an operating method thereof, and a memory system.

In order to achieve the above object, the technical solutions of the examples of the present disclosure are implemented as follows:

According to a first aspect, the present disclosure provides a memory device, comprising a memory array and a peripheral circuit coupled to the memory array, wherein the peripheral circuit is configured to:

perform a first detection operation on a plurality of memory cells in the memory array and coupled to a target word line to obtain a first detection result, wherein the first detection operation comprises a plurality of read phases, read voltages with different magnitudes are applied to the target word line in different read phases, and the first detection result comprises detection states of the plurality of read phases comprised in the first detection operation; and

perform a second detection operation on the plurality of memory cells coupled to the target word line based on the first detection result, wherein a number of read phases comprised in the second detection operation is obtained based on the detection states of the plurality of read phases comprised in the first detection operation.

In an alternative implementation, the peripheral circuit is further configured to:

perform N sensing operations in a first read phase, wherein the N sensing operations are performed at N different timings in the first read phase, respectively, and the first read phase is one of the plurality of read phases comprised in the first detection operation, wherein the N is an integer greater than 1; and

obtain a detection state of the first read phase based on sensing results of the N sensing operations in the first read phase.

In an alternative implementation, the peripheral circuit is configured to:

obtain a number of memory cells in a first memory state in the plurality of memory cells based on a sensing result of a sensing operation in the first read phase, wherein the sensing operation is any one of the N sensing operations, a threshold voltage of a memory cell in the first memory state is less than a compensation read voltage corresponding to a timing at which the sensing operation is performed; and the compensation read voltage is greater than or equal to a read voltage of the first read phase.

In an alternative implementation, the N is an integer greater than 3; and the peripheral circuit is configured to:

obtain N-1 differences based on the sensing results of the N sensing operations in the first read phase, wherein any one of the N-1 differences is a difference between numbers of memory cells in the first memory state obtained based on sensing results of two adjacent sensing operations in the N sensing operations, and the first detection result further comprises a change trend of the N-1 differences; and

obtain the detection state of the first read phase based on the change trend of the N-1 differences.

In an alternative implementation, the peripheral circuit is further configured to:

mark the detection state of the first read phase, wherein if the change trend of the N-1 differences is increasing or decreasing, the detection state of the first read phase is marked as a first state, and if the change trend of the N-1 differences is first decreasing and then increasing, the detection state of the first read phase is marked as a second state.

In an alternative implementation, a number of read phases comprised in the second detection operation is a difference between a number of read phases comprised in the first detection operation and a number of read phases, whose detection states are the second state, in the plurality of read phases comprised in the first detection operation.

In an alternative implementation, the detection state of the first read phase is the first state, and the peripheral circuit is further configured to:

obtain a read voltage of a second read phase corresponding to the first read phase based on the read voltage of the first read phase and the change trend of the N-1 differences, wherein the second read phase is a read phase in the second detection operation.

In an alternative implementation, the detection state of the first read phase is the second state, and the peripheral circuit is further configured to:

obtain a read reference voltage corresponding to the first read phase based on the change trend of the N-1 differences in the first read phase and compensation read voltages corresponding to timings at which the N sensing operations are performed, wherein the first detection result further comprises the read reference voltage.

In an alternative implementation, the plurality of memory cells coupled to the target word line are configured to store M pages of data, the M is a positive integer, and the peripheral circuit is configured to:

perform a plurality of detection operations on the plurality of memory cells coupled to the target word line to obtain a plurality of read reference voltages, wherein the first detection operation and the second detection operation are two adjacent detection operations in the plurality of detection operations; and

perform a read operation on the plurality of memory cells coupled to the target word line through the plurality of read reference voltages to obtain a page of data in the M pages of data.

According to a second aspect, the present disclosure provides a memory system comprising:

at least one memory device comprising:

a memory array; and

a peripheral circuit coupled to the memory array; the peripheral circuit is configured to:

perform a first detection operation on a plurality of memory cells in the memory array and coupled to a target word line to obtain a first detection result, wherein the first detection operation comprises a plurality of read phases, read voltages with different magnitudes are applied to the target word line in different read phases, and the first detection result comprises detection states of the plurality of read phases comprised in the first detection operation; and

perform a second detection operation on the plurality of memory cells coupled to the target word line based on the first detection result, wherein a number of read phases comprised in the second detection operation is obtained based on the detection states of the plurality of read phases comprised in the first detection operation; and

a controller coupled with the at least one memory device and configured to control the at least one memory device.

In an alternative implementation, the controller is configured to: send a first detection command;

the peripheral circuit is configured to: perform the first detection operation in response to the first detection command; and send the first detection result to the controller;

the controller is further configured to: generate a second detection command based on the first detection result; and

the peripheral circuit is further configured to: perform the second detection operation in response to the second detection command.

According to a third aspect, the present disclosure provides an operating method of a memory device, comprising:

performing a first detection operation on a plurality of memory cells in a memory array and coupled to a target word line to obtain a first detection result, wherein the first detection operation comprises a plurality of read phases, read voltages with different magnitudes are applied to the target word line in different read phases, and the first detection result comprises detection states of the plurality of read phases comprised in the first detection operation; and

performing a second detection operation on the plurality of memory cells coupled to the target word line based on the first detection result, wherein a number of read phases comprised in the second detection operation is obtained based on the detection states of the plurality of read phases comprised in the first detection operation.

In an alternative implementation, the operating method further comprises:

performing N sensing operations in a first read phase, wherein the N sensing operations are performed at N different timings in the first read phase, respectively, the first read phase is one of the plurality of read phases comprised in the first detection operation, and the N is an integer greater than 1; and

obtaining a detection state of the first read phase based on sensing results of the N sensing operations in the first read phase.

In an alternative implementation, the operating method further comprises:

obtaining a number of memory cells in a first memory state in the plurality of memory cells based on a sensing result of a sensing operation in the first read phase, wherein the sensing operation is any one of the N sensing operations, a threshold voltage of a memory cell in the first memory state is less than a compensation read voltage corresponding to a timing at which the sensing operation is performed, and the compensation read voltage is greater than or equal to a read voltage of the first read phase.

In an alternative implementation, obtaining the detection state of the first read phase based on the sensing results of the N sensing operations in the first read phase comprises:

obtaining N-1 differences based on the sensing results of the N sensing operations in the first read phase, wherein any one of the N-1 differences is a difference between numbers of memory cells in the first memory state obtained based on sensing results of two adjacent sensing operations in the N sensing operations, the first detection result further comprises a change trend of the N-1 differences, and the N is an integer greater than 3; and

obtaining the detection state of the first read phase based on the change trend of the N-1 differences.

In an alternative implementation, the operating method further comprises:

marking the detection state of the first read phase, wherein if the change trend of the N-1 differences is increasing or decreasing, the detection state of the first read phase is marked as a first state, and if the change trend of the N-1 differences is first decreasing and then increasing, the detection state of the first read phase is marked as a second state.

In an alternative implementation, a number of read phases comprised in the second detection operation is a difference between a number of read phases comprised in the first detection operation and a number of read phases, whose detection states are the second state, in the plurality of read phases comprised in the first detection operation.

In an alternative implementation, the detection state of the first read phase is the first state, and the operating method further comprises:

obtaining a read voltage of a second read phase corresponding to the first read phase based on a read voltage of the first read phase and the change trend of the N-1 differences, wherein the second read phase is a read phase in the second detection operation.

In an alternative implementation, the detection state of the first read phase is the second state, and the operating method further comprises:

obtaining a read reference voltage corresponding to the first read phase based on the change trend of the N-1 differences in the first read phase and compensation read voltages corresponding to timings at which the N sensing operations are performed, wherein the first detection result further comprises the read reference voltage.

In an alternative implementation, the operating method comprises:

performing a plurality of detection operations on the plurality of memory cells coupled to the target word line to obtain a plurality of read reference voltages, wherein the first detection operation and the second detection operation are two adjacent detection operations in the plurality of detection operations; and

performing a read operation on the plurality of memory cells coupled to the target word line through the plurality of read reference voltages to obtain a page of data in M pages of data stored in the plurality of memory cells, wherein the M is a positive integer..

### BRIEF DESCRIPTION OF THE DRAWINGS

FIG. 1 is a schematic diagram of an electronic device comprising a memory system according to an example of the present disclosure;

FIG. 2 is a schematic diagram of a memory card according to an example of the present disclosure;

FIG. 3 is a schematic diagram of a solid state disk according to an example of the present disclosure;

FIG. 4 is a first schematic diagram of a memory device according to an example of the present disclosure;

FIG. 5 is a second schematic diagram of a memory device according to an example of the present disclosure;

FIG. 6 is a schematic diagram of threshold voltage distribution of memory cells coupled to a target word line according to an example of the present disclosure;

FIG. 7 is a schematic diagram of two adjacent threshold voltage portions according to an example of the present disclosure;

FIG. 8 is a voltage curve for performing a first detection operation and a second detection operation according to an example of the present disclosure;

FIG. 9 is a schematic diagram of a first read phase according to an example of the present disclosure;

FIG. 10 is a schematic diagram of a memory system according to an example of the present disclosure; and

FIG. 11 is a schematic flowchart of an operating method of a memory device according to an example of the present disclosure..

### DETAILED DESCRIPTION

Example implementations disclosed in the present disclosure will be described in more detail below with reference to the accompanying drawings. Although example implementations of the present disclosure are shown in the accompanying drawings, it should be understood that the present disclosure may be implemented in various forms and should not be limited to the implementations set forth herein. Rather, these implementations are provided so that the present disclosure can be more thoroughly understood and the scope disclosed in the present disclosure can be fully conveyed to those skilled in the art.

In the following description, numerous details are given in order to provide a more thorough understanding of the present disclosure. However, it will be apparent to one skilled in the art that, the present disclosure may be practiced without one or more of these details. In other examples, in order to avoid confusion with the present disclosure, some technical features known in the art are not described; for example, not all features of the actual examples are described here, and well-known functions and structures are not described in detail.

In the accompanying drawings, like reference numerals refer to like elements throughout.

It should be understood that spatial relation terms such as “beneath”, “below”, “lower”, “under”, “over”, “upper”, etc., may be used herein for ease of description to describe the relationship between one element or feature and other elements or features shown in the figures. It should be appreciated that, in addition to the orientations shown in the figures, the spatial-relation terms intent to also comprise different orientations of the devices in use and operation. For example, if the devices in the figures are flipped, then the devices described as “below” or “under” or “beneath” other elements or features will be oriented “on” other elements or features. Thus, the example terms “below” and “beneath” may comprise both upper and lower orientations. The devices may be additionally oriented (rotated 90 degrees or other orientations) and the spatial description terminology used herein is interpreted accordingly.

A term used herein is for the purpose of describing a particular example only and is not to limit the present disclosure. As used herein, the singular forms "a", "an" and "said/the" are intended to comprise the plural forms as well, unless the context clearly dictates otherwise. It should also be understood that at least one of the terms "consists of" or "comprising", when used in this description, identify the presence of at least one of stated features, integers, steps, operations, elements or parts, but do not exclude the presence or addition of at least one of one or more other features, integers, steps, operations, elements, parts or groups. As used herein, the term "at least one of" comprises any and all combinations of associated listed items.

The memory system in the examples of the present disclosure comprises, but is not limited to, a memory system comprising a three-dimensional NAND type memory, and for ease of understanding, the memory system according to the present disclosure will be described by taking a memory system comprising a three-dimensional NAND type memory as an example.

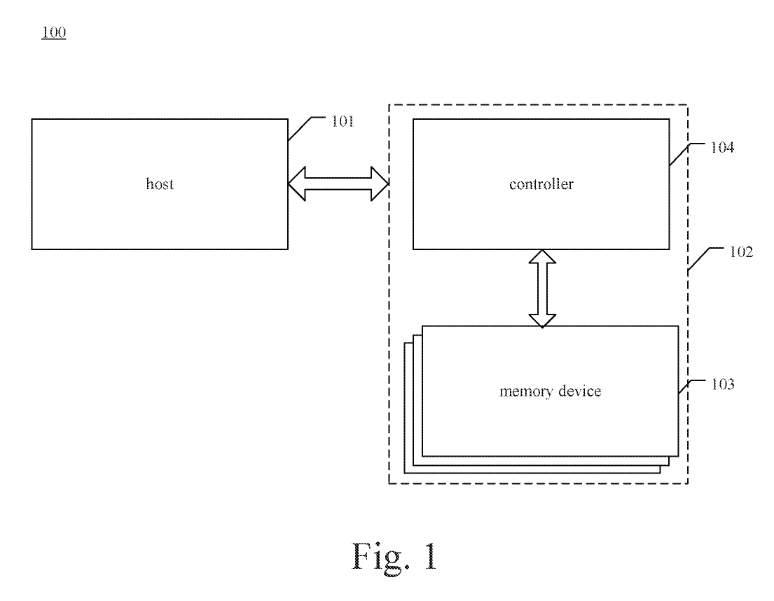

FIG. 1 is a schematic diagram of an example system with a memory system according to an example of the present disclosure. In an example of the present disclosure, the system 100 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a memory therein. As shown in FIG. 1, the system 100 may comprise a host-side device 101 and a memory system 102 which may comprise one or more memory devices 103 and a controller 104. The host-side device 101 may comprise a processor of an electronic device, for example, a central processing unit (CPU), or a system on a chip (SoC), for example, an application processor (AP). The host-side device 101 may be configured to send or receive data to or from the memory system 102.

In some implementations, the controller 104 is coupled to the memory device 103 and the host-side device 101 and is configured to control the memory device 103. The controller 104 may manage data stored in the memory device 103 and communicate with the host-side device 101. In some examples, the controller 104 is designed to operate in a low duty cycle environment, such as in a secure digital card, compact flash card (CFC), universal serial bus (USB) flash drive, or to operate in other medium for use in electronic devices such as personal computers, digital cameras, mobile phones, and the like. In other implementations, the controller 104 is designed to operate in a high duty cycle environment, such as in a solid state disk or embedded Multi-Media Card (eMMC).

In some examples, the controller 104 and the one or more memory devices 103 may be integrated into various types of storage devices, for example, the memory system 102 may be implemented and packaged into different types of terminal electronics.

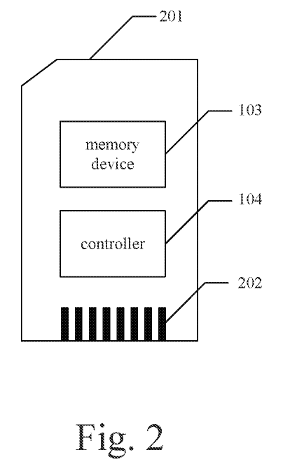

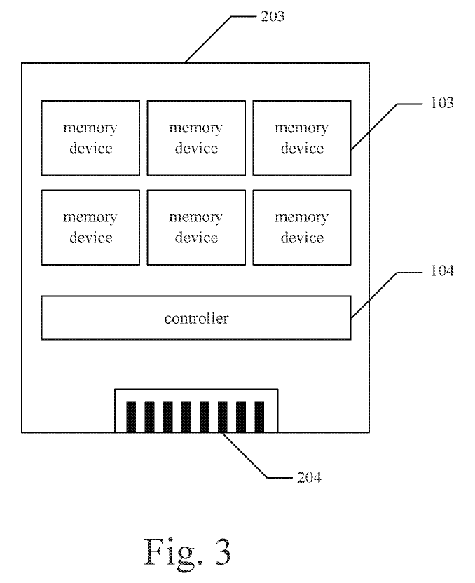

In one example as shown in FIG. 2, the controller 104 and the single memory device 103 may be integrated into the memory card 201. The memory card 201 may be one of a compact flash memory card, a smart media card (SMC), a memory stick (MS), a multimedia card (MMC) such as an RS-MMC, an MMCmicro, an eMMC, or the like, a secure digital card such as a Mini SD card, a Micro SD card, an SDHC card, or the like, and a universal flash memory card. The memory card 201 may also comprise a memory card connector 202 that couples the memory card 201 with a host-side device (e.g., host-side device 101 in FIG. 1). In another example as shown in FIG. 3, the controller 104 and a plurality of memory devices 103 may be integrated into an SSD 203. The SSD 203 may also comprise an SSD connector 204 that couples the SSD 203 with a host-side device (e.g., the host-side device 101 in FIG. 1). In some implementations, at least one of the storage capacity or operating speed of the SSD 203 is greater than that of the memory card 201.

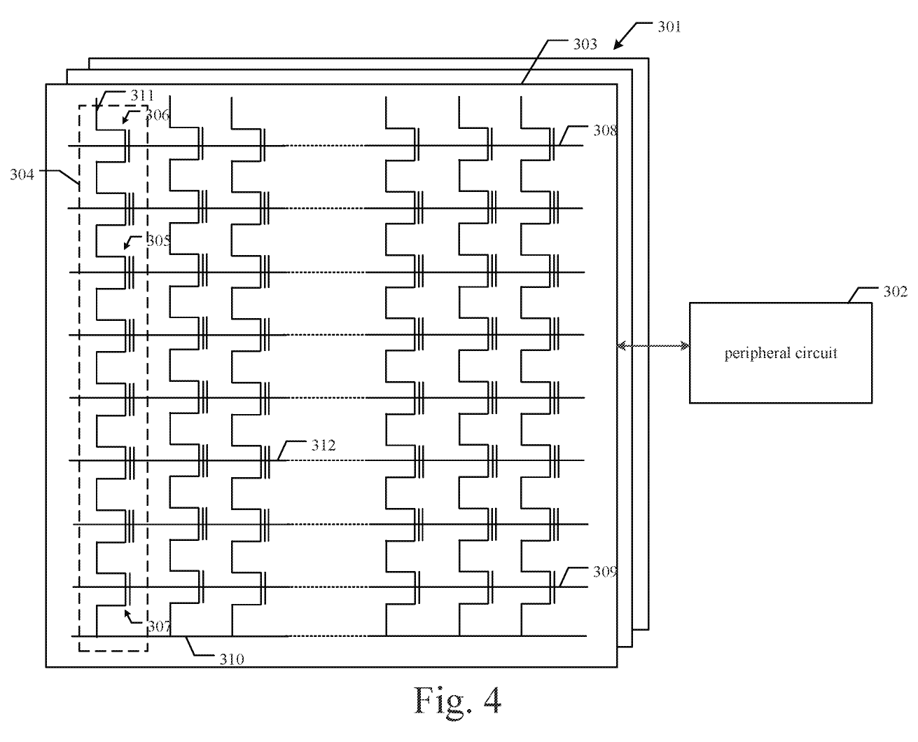

FIG. 4 is a schematic circuit diagram of an example memory device 300 comprising a peripheral circuit according to an example of the present disclosure. The memory device 300 may be an example of the memory device 103 in FIG. 1. The memory device 300 may comprise a memory array 301 and a peripheral circuit 302 coupled to the memory array 301. Taking the memory array 301 as an example of a 3D NAND type memory array for description, the memory cell 305 is a NAND memory cell, the memory cell 305 is provided in the form of an array of memory cell strings 304, and each memory cell string 304 extends vertically above a substrate (not shown). In some implementations, each memory cell string 304 comprises a plurality of memory cells 305 coupled in series and stacked vertically. Each memory cell 305 may maintain a continuous analog value, e.g., voltage or charge, which depends on the number of electrons trapped within a region of the memory cell 305. Each memory cell 305 can be either a floating gate type of memory cell comprising a floating-gate transistor or a charge trap type of memory cell comprising a charge-trap transistor.

In some implementations, each memory cell 305 is a single level cell (SLC) having two possible memory states and thus may store one bit of data. For example, the first memory state “0” may correspond to a first voltage range and the second memory state “1” may correspond to a second voltage range. In some implementations, each memory cell 305 is a multi-level cell capable of storing more than a single bit of data in four or more memory states, e.g., a multi-level cell (MLC) storing two bits per cell, a triple level cell (TLC) storing three bits per cell, or a quad-level cell (QLC) storing four bits per cell.

As shown in FIG. 4, each memory cell string 304 may comprise a bottom select transistor (BST) 307 at its source end and a top select transistor (TST) 306 at its drain end. The bottom select transistor 307 and the top select transistor 306 may be configured to activate a selected memory cell string 304 during read and program operations. In some implementations, the sources of the memory cell strings 304 in the same memory block 303 may be coupled through a common source line (CSL) 310. In other words, all the memory cell strings 304 in the same memory block 303 have an array common source (ACS). According to some implementations, the top select transistor 306 of each memory cell string 304 is coupled to a respective bit line (BL) 311 from which data can be read or written via an output bus (not shown). In some implementations, each memory cell string 304 is configured to be selected or deselected by at least one of applying a select voltage (e.g., a voltage higher than a threshold voltage of the top select transistor 306) or a deselect voltage (e.g., 0V) to a top select gate (TSG) of the respective top select transistor 306 through one or more top select lines (TSL) 308 or applying a select voltage (e.g., a voltage higher than a threshold voltage of the bottom select transistor 307) or a deselect voltage (e.g., 0V) to a bottom select gate (BSG) of the respective bottom select transistor 307 through one or more bottom select lines (BSL) 309.

As shown in FIG. 4, the memory cell string 304 may be organized into a plurality of memory blocks 303, each of which may have a common source line 310. In some implementations, each memory block 303 is a basic data unit for an erase operation, e.g., all memory cells 305 in the same memory block 303 are erased simultaneously. To erase the memory cells 305 in the selected memory block, a common source line 310 coupled to the selected memory block and an unselected memory block in the same plane as the selected memory block may be biased with an erase voltage. It should be understood that, in some examples, erase operations may be performed at a level of half-memory block, at a level of quarter-memory block, or at a level of any suitable number of memory blocks or any suitable fraction of a memory block. The memory cells 305 of adjacent memory cell strings 304 may be coupled by word lines 312 that select which rows of memory cells 305 are affected by read or program operations.

In some examples, the peripheral circuit 302 may comprise any suitable analog, digital, and mixed-signal circuit to enable operations of the memory array 301 by applying at least one of a voltage signal or a current signal to and sensing at least one of a voltage signal or a current signal from each of target memory cells 305 through the bit lines 311, the word lines 312, the common source lines 310, the bottom select lines 309, and the top select lines 308. The peripheral circuit 302 may comprise various types of peripheral circuits formed using metal-oxide-semiconductor technology.

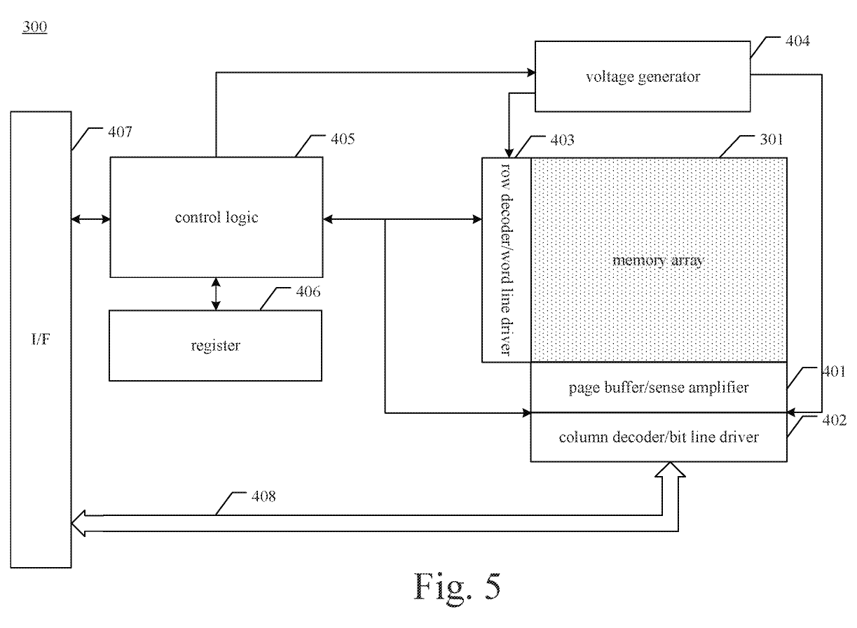

FIG. 5 shows some example peripheral circuits 302 comprising a page buffer/sensing amplifier 401, a column decoder/bit line driver 402, a row decoder/word line driver 403, a voltage generator 404, a control logic 405, a register 406, a flash memory interface 407, and a data bus 408. It should be understood that, in some examples, additional peripheral circuits not shown in FIG. 5 may also be comprised.

The page buffer/sensing amplifier 401 may be configured to read data from and program (write) data to the memory array 301 according to control signals from the control logic 405. In one example, the page buffer/sensing amplifier 401 may store a page of programming data (written data) to be programmed to the memory array 301. In another example, the page buffer/sensing amplifier 401 may perform a programming verification operation to ensure that data has been properly programmed into memory cells coupled to the selected word line. In yet another example, the page buffer/sensing amplifier 401 may also sense a low power signal from the bit line representing a data bit stored in the memory cell, and amplify a small voltage swing to an identifiable logic level in a read operation. The column decoder/bit line driver 402 may be configured to be controlled by the control logic 405 and select one or more memory cell strings by applying a bit line voltage generated from the voltage generator 404.

The row decoder/word line driver 403 may be configured to be controlled by the control logic 405 and select/deselect a memory block of the memory array 301 and select/deselect a word line of the memory block. The row decoder/word line driver 403 may also be configured to drive a word line using the word line voltage generated from the voltage generator 404. In some implementations, the row decoder/word line driver 403 may also select/deselect and drive the bottom select line and the top select line. As described in detail below, the row decoder/word line driver 403 is configured to perform a program operation on memory cells coupled to the selected word line (s). The voltage generator 404 may be configured to be controlled by the control logic 405 and generate word line voltages (e.g., read voltages, program voltages, pass voltages, local voltages, verify voltages, etc.), bit line voltages, and source line voltages to be supplied to the memory array 301.

The control logic 405 may be coupled to each peripheral circuit described above and configured to control operations of each peripheral circuit. The register 406 may be coupled to the control logic 405 and comprise a status register, a command register, and an address register for storing status information, command operation codes (OP codes), and command addresses for controlling operations of each peripheral circuit. The flash memory interface 407 may be coupled to the control logic 405 and act as a control buffer to buffer control commands received from a host-side device (not shown) and relay them to the control logic 405 and buffer status information received from the control logic 405 and relay it to a controller. The flash memory interface 407 may also be coupled to the column decoder/bit line driver 402 via the data bus 408, and act as a data I/O interface and a data buffer to buffer and relay data to or from the memory array 301.

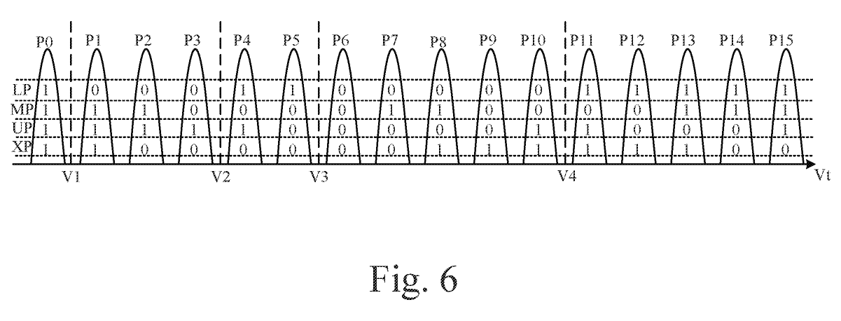

In some examples, the data stored in the multi-level cell may be read in a single-page read manner. Taking the memory cell being a quad-level cell QLC as an example, FIG. 6 is a schematic diagram of a threshold voltage distribution of memory cells coupled to a target word line, each memory cell stores four bits of data, a threshold voltage of each memory cell is within a range of one of a plurality of threshold voltage distributions corresponding to an erased state P0 and fifteen programmed states P1 to P15, each threshold voltage distribution corresponds to a Gray code, and data stored in a plurality of memory cells may be logically divided into four pages based on a encoding manner of Gray code, comprising an upper page UP, a middle page MP, a lower page LP, and an extra page XP. Taking the data of the lower page LP being read by a single-page read manner as an example, the read voltage V1, the read voltage V2, the read voltage V3 and the read voltage V4 may be applied to the target word line. Herein, the encoding manner of the Gray code is only an example, and when different encoding manners are configured to encode the Gray code, the numbers and the magnitudes of the read voltages required to apply to read the data of each page are different, and the specific encoding manner of the Gray code is not limited in the present disclosure.

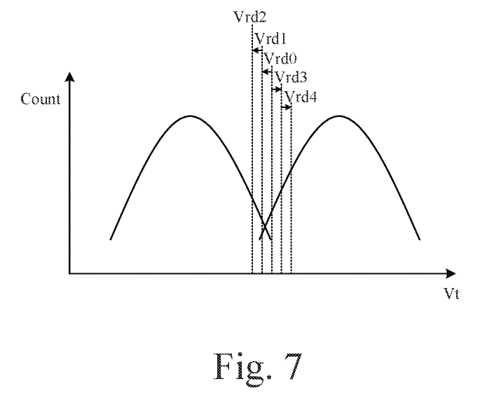

In the read method according to the above examples, the read voltage applied to the target word line is a default read voltage in some examples, however, the threshold voltage of the memory cell may change over time or due to the influence of environmental factors (e.g., temperature), which may in turn lead to offset and/or broadening of the threshold voltage distribution. FIG. 7 is a schematic diagram of two adjacent threshold voltage distributions. Referring to FIG. 7, two adjacent threshold voltage distributions may overlap, and after the threshold voltage distribution offsets and/or broadens, if the read operation continues to be performed using the default read voltage Vrd0, more fail bit counts (FBC) may be generated, in which case, the valley search operation may be configured to re-determine the read voltage to improve the reliability of the read operation.

In some examples, with continued reference to FIG. 7, the valley search operation may comprise a plurality of single level read operations, for example, the read voltages Vrd0, Vrd1, Vrd2, Vrd3, and Vrd4 may be configured to perform a single level read operation, where the read voltages Vrd1, Vrd2, Vrd3, and Vrd4 are all the compensation read voltages obtained based on the default read voltage Vrd0, the change trend of the number of the memory cells whose threshold voltages are less than the read voltage may be obtained based on the read results of the plurality of single level read operations, and the read reference voltage may be obtained based on the change trend, for example, the read reference voltage herein may be Vrd1, and the magnitude of the read reference voltage may be equal to the default read voltage Vrd0 minus a compensation value.

However, with reference to FIGS. 6 and 7, when the memory cell is a QLC or another multi-level cell, the number of the valley bottoms between adjacent threshold voltage distributions is relatively large, a plurality of valley search operations need to be performed to obtain a plurality of read reference voltages corresponding to the plurality of valley bottoms, and each valley search operation comprises a plurality of single level read operations, which may result in a need to spend a long time to search for all read reference voltages, resulting in a lower efficiency of the read operation and affecting the overall performance of the memory device. In this regard, the present disclosure provides the following implementations.

The present disclosure provides a memory device, with reference to FIGS. 4 and 5, the memory device 300 comprises a memory array 301 and a peripheral circuit 302 coupled to the memory array 301, and the peripheral circuit 302 may be configured to: perform a first detection operation on a plurality of memory cells in the memory array 301 and coupled to a target word line 312 to obtain a first detection result, wherein the first detection operation comprises a plurality of read phases, and read voltages with different magnitudes are applied to the target word line 312 in different read phases, the first detection result comprises detection states of the plurality of read phases comprised in the first detection operation; and perform a second detection operation on the plurality of memory cells coupled to the target word line 312 based on the first detection result, wherein a number of the read phases comprised in the second detection operation is obtained based on the detection states of the plurality of read phases comprised in the first detection operation. Here, the target word line 312 may be any word line 312 in the memory array 301.

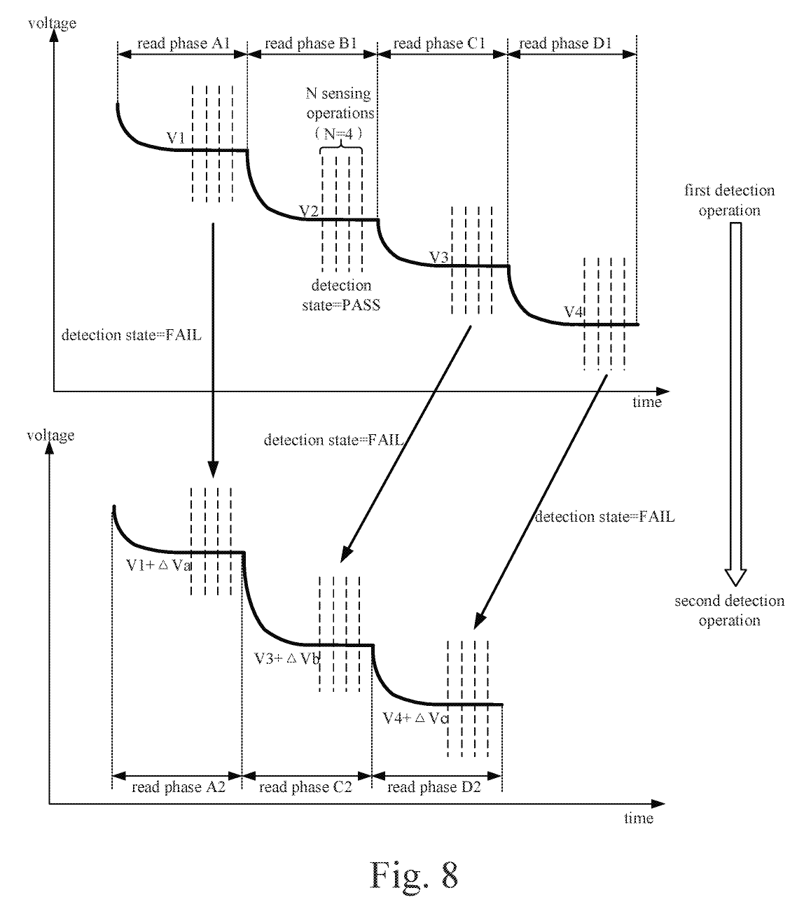

FIG. 8 is a voltage curve for performing a first detection operation and a second detection operation according to an example of the present disclosure. Referring to FIG. 8, the first detection operation comprises a plurality of read phases, here, taking the first detection operation comprising four read phases (a read phase A1, a read phase B1, a read phase C1, and a read phase D1) as an example, the peripheral circuit 302 may be configured to apply different read voltages to the target word line in different read phases.

In some specific examples, with reference to FIGS. 6 and 8 together, the first detection operation may be performed for a plurality of valley bottoms of one logical page, for example, if the first detection operation may be performed for four valley bottoms of the lower page LP, the read voltages of the four read phases comprised in the first detection operation may be four read voltages V1, V2, V3, and V4 configured to read the lower page LP, respectively. Here, as an example, four read voltages are applied to the target word line in a descending order of the read voltages, but the present disclosure is not limited thereto, and in some other examples, the read voltages may also be applied to the target word line in an ascending order of the read voltages, which is not specifically limited in the present disclosure.

In the examples of the present disclosure, the valley search operation may be performed in units of logical page, and the efficiency of the valley search operation may be improved relative to a valley search operation performed in units of valley bottom.

In some examples, the peripheral circuit 302 is further configured to: perform N sensing operations in a first read phase, wherein the N sensing operations are performed at N different timings in the first read phase, respectively, the first read phase is one of the plurality of read phases comprised in the first detection operation, and N is an integer greater than 1; and obtain a detection state of the first read phase based on sensing results of the N sensing operations in the first read phase.

In some examples, the peripheral circuit 302 is, in some examples, configured to: obtain a number of memory cells in a first memory state in the plurality of memory cells based on a sensing result of a sensing operation in the first read phase. Here, the sensing operation is any one of the N sensing operations performed in the first read phase; a threshold voltage of a memory cell in the first memory state is less than a compensation read voltage corresponding to a timing at which the sensing operation is performed; and the compensation read voltage is greater than or equal to a read voltage of the first read phase.

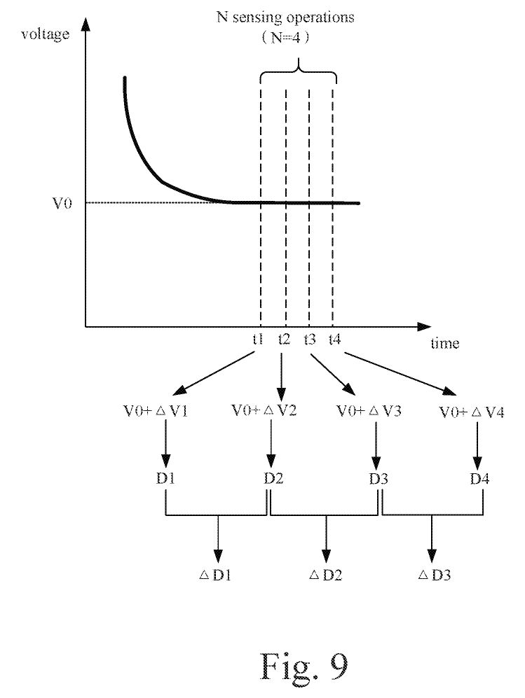

FIG. 9 is a schematic diagram of a first read phase according to an example of the present disclosure, referring to FIG. 9, the peripheral circuit 302 may be configured to: in a first read phase, apply a read voltage V0 to the target word line, and after the voltage on the target word line is stabilized at the read voltage V0, perform N sensing operations, wherein the N sensing operations are respectively performed at N different timings in the first read phase, here, taking N=4 as an example, the read phase comprises four sensing operations performed at t1, t2, t3, and t4, respectively; and the read voltage V0 may be equal to any read voltage of V1, V2, V3, and V4.

It can be understood that, when the read voltage V0 is applied to the target word line, for a memory cell in the plurality of memory cells coupled to the target word line, whose threshold voltage is less than the read voltage V0, the larger the difference between the read voltage V0 and the threshold voltage of the memory cell is, the faster the memory cell is turned on, and the smaller the difference between the read voltage V0 and the threshold voltage of the memory cell is, the slower the memory cell is turned on. Therefore, when the sensing operation is performed at different timings, the numbers of the memory cells in the first memory state obtained based on the sensing result are different, here, the threshold voltage of the memory cell in the first memory state is less than the compensation read voltage corresponding to the timing at which the sensing operation is performed. In an example, referring to FIG. 9, the magnitude of the compensation read voltage corresponding to the timing t1 at which the first sensing operation is performed may be equal to V0+ΔV1, and the number of the memory cells in the first memory state obtained based on the sensing result may be D1; the magnitude of the compensation read voltage corresponding to the timingt2 at which the second sensing operation is performed may be equal to V0+ΔV2, and the number of the memory cells in the first memory state obtained based on the sensing result may be D2; the magnitude of the compensation read voltage corresponding to the timing t3 at which the third sensing operation is performed may be equal to V0+ΔV3, and the number of the memory cells in the first memory state obtained based on the sensing result may be D3; the magnitude of the compensation read voltage corresponding to the timing t4 at which the fourth sensing operation is performed may be equal to V0+ΔV4, and the number of the memory cells in the first memory state obtained based on the sensing result may be D4, and ΔV4 > ΔV3 > ΔV2 > ΔV1, and D4 > D3 > D2 > D1.

In the example of the present disclosure, one read phase may comprise a plurality of sensing operations performed at different timings, so that a plurality of offsets of the read voltage may be simulated in a case that the read voltage on the target word line is kept unchanged, and compared with a method of performing a read operation with different read voltages for multiple times, the efficiency of valley search may be greatly improved for one valley bottom.

In some examples, the peripheral circuit 302 is configured to: obtain N-1 differences based on the sensing results of the N sensing operations in the first read phase, wherein any one of the N-1 differences is a difference between the numbers of the memory cells in the first memory state obtained based on sensing results of two adjacent sensing operations in the N sensing operations, the first detection result further comprises a change trend of the N-1 differences; and obtain the detection state of the first read phase based on the change trend of the N-1 differences. For example, referring to FIG. 9, the peripheral circuit 302 may be configured to obtain three differences based on the sensing results of the four sensing operations in the first read phase, where the three differences may be ΔD1, ΔD2, and ΔD3, respectively, and ΔD1=D2-D1, ΔD2=D3-D2, ΔD3=D4-D3. The peripheral circuit 302 may be configured to obtain the detection state of the first read phase based on the change trend of ΔD1, ΔD2 and ΔD3.

In the example of the present disclosure, the change trend of the N-1 difference values may be one of increasing, decreasing, or first decreasing and then increasing, and in an example, when the change trend of the N-1 difference values is increasing, representing that the N compensation read voltages corresponding to the N timings at which the N sensing operations are performed are all greater than the read reference voltage, then the detection state should be failed, representing that the read reference voltage has not been determined; when the change trend of the N-1 difference values is decreasing, representing that the N compensation read voltages corresponding to the N timings at which the N sensing operations are performed are all less than the read reference voltage, then the detection state should also be failed; and when the change trend of the N-1 difference values is first decreasing and then increasing, representing that the N compensation read voltages corresponding to the N timings at which the N sensing operations are performed comprise the compensation read voltage greater than the read reference voltage and also the compensation read voltage less than the read reference voltage, then the detection state should be passed, representing that the read reference voltage can be determined.

In some examples, the peripheral circuit 302 is further configured to: mark the detection state of the first read phase; wherein if the change trend of the N-1 differences is increasing or decreasing, the detection state of the first read phase is marked as a first state; and if the change trend of the N-1 differences is first decreasing and then increasing, the detection state of the first read phase is marked as a second state.

In some examples, the detection state of the first read phase is the second state, and the peripheral circuit 302 is further configured to: obtain a read reference voltage corresponding to the first read phase based on the change trend of the N-1 differences in the first read phase and compensation read voltages corresponding to the timings at which the N sensing operations are performed. For example, referring to FIG. 9, if ΔD2 is a minimum value in ΔD1, ΔD2, and ΔD3, V0+ΔV2 or V0+ΔV3 may be used as the read reference voltage corresponding to the first read phase, or the read reference voltage may be determined based on the change trend of ΔD1, ΔD2 and ΔD3 by a fitting algorithm, in which case, the read reference voltage may not be equal to any one of the compensation read voltages.

In the example of the present disclosure, the method for obtaining the detection state of the first read phase according to the above examples may obtain the detection states of the plurality of read phases in the first detection operation, and the peripheral circuit 302 may mark the detection states of the plurality of read phases in the first detection operation.

In a specific example, referring to FIG. 8, the detection states of the read phase A1, the read phase C1, and the read phase D1 may each be the first state (FAIL), and the detection state of the read phase B1 may be the second state (PASS).

In some examples, a number of the read phases comprised in the second detection operation is a difference between a number of the read phases comprised in the first detection operation and a number of the read phases whose detection states are the second state in the plurality of read phases comprised in the first detection operation. For example, referring to FIG. 8, the first detection operation comprises four read phases, and the number of the read phases whose detection states are the second state in the four read phases is one, and the number of the read phases comprised in the second detection operation is three.

In the example of the present disclosure, since the offset degrees of different threshold voltage distributions may be different, the progress of the valley search performed for different valley bottoms in the threshold voltage distribution may be different, for example, for the valley bottom corresponding to the read phase B1 in the first detection operation, the read reference voltage of the valley bottom can be determined in the first detection operation, but for the valley bottom corresponding to the read phase A1, the read phase C1, and the read phase D1, the read reference voltage of the valley bottom cannot be determined by the first detection operation, and at least one more detection operation needs to be performed, for example, the second detection operation, and in the process of performing the second detection operation, the read phase corresponding to the read phase B1 may be omitted, but only the read phase A2 corresponding to the read phase A1, the read phase C2 corresponding to the read phase C1, and the read phase D2 corresponding to the read phase D1 may be comprised, thereby shortening the time for performing the next detection operation, and further improving the efficiency of performing the valley search operation.

In some specific examples, referring to FIG. 5, the control logic 405 in the peripheral circuit 302 may be configured to: store detection states of a plurality of read phases in the detection operation in the register 406 after performing the detection operation, and when performing the next detection operation, the detection states of the plurality of read phases may be obtained from the register 406 to determine which read phases may be omitted, and after the next detection operation is completed, the detection state of the read phase may be updated.

In some examples, the detection state of the first read phase may be the first state, and the peripheral circuit 302 is further configured to: obtain a read voltage of a second read phase corresponding to the first read phase based on a read voltage of the first read phase and the change trend of the N-1 differences, wherein the second read phase is a read phase in the second detection operation. In an example, if the change trend of the N-1 difference values is increasing, the read voltage of the second read phase may be equal to the read voltage of the first read phase plus a negative compensation value, and if the change trend of the N-1 difference values is decreasing, the read voltage of the second read phase may be equal to the read voltage of the first read phase plus a positive compensation value.

In the example of the present disclosure, for the read phase whose detection state is the first state in the previous detection operation, a read voltage of a read phase corresponding to the read phase in the next detection operation may be obtained based on the read voltage of the read phase and the change trend of the N-1 differences. For example, referring to FIG. 8, the read voltage of the read phase A2 corresponding to the read phase A1 may be the read voltage V1 of the read phase A1 plus the compensation value ΔVa, the read voltage of the read phase C2 corresponding to the read phase C1 may be the read voltage V3 of the read phase C1 plus the compensation value ΔVb, and the read voltage of the read phase D2 corresponding to the read phase D1 may be the read voltage V4 of the read phase D1 plus the compensation value ΔVc. Here, the compensation values ΔVa, ΔVb, and ΔVc may be positive or negative values.

In some examples, the plurality of memory cells coupled to the target word line are configured to store M pages of data, wherein M is a positive integer; and the peripheral circuit 302 is configured to: perform a plurality of detection operations on the plurality of memory cells coupled to the target word line to obtain a plurality of read reference voltages, wherein the first detection operation and the second detection operation are two adjacent detection operations of the plurality of detection operations; and perform a read operation on the plurality of memory cells coupled to the target word line through the plurality of read reference voltages to obtain a page of data in the M pages of data. For example, with reference to FIGS. 6 and 8 together, taking M being equivalent to 4 as an example, the performing of a plurality of detection operations on the plurality of memory cells coupled to the target word line may obtain four read reference voltages, and the first detection operation and the second detection operation are two adjacent detection operations in the plurality of detection operations; and the performing of a read operation on the plurality of memory cells coupled to the target word line through four read reference voltages may obtain a page of data (the lower page LP) in the four pages of data.

In an example of the present disclosure, the peripheral circuit may be configured to perform a valley search operation in a relatively high efficiency manner. According to the first aspect, the valley search operation for the multi-level cell is performed in units of logical page, and the valley search operation for one logical page may comprise a plurality of detection operations, and one detection operation may comprise a plurality of read phases, one read phase may correspond to one valley bottom, and the efficiency is higher compared to the valley search method in which one detection operation is only for one valley bottom; according to the second aspect, after one detection operation is performed, the detection state of each read phase in the detection operation may be marked, and for the read phase for which the read reference voltage can be determined, for example, the read phase whose detection state is the second state, a read phase corresponding to the read phase may be omitted in the next detection operation, so that the time of the next detection operation may be shortened, and the overall efficiency of the valley search operation can be improved; according to a third aspect, one read phase may comprise N sensing operations performed at different timings, the multiple offsets of the read voltage may be simulated in the case that the read voltage of the target word line is kept unchanged, and the efficiency is higher compared to the valley search method in which a plurality of read operations with different read voltages are performed.

Based on a similar concept as the above memory device, the present disclosure further provides a memory system, comprising: the memory device in any one of the above examples; a controller coupled to the at least one memory device and configured to control the memory device.

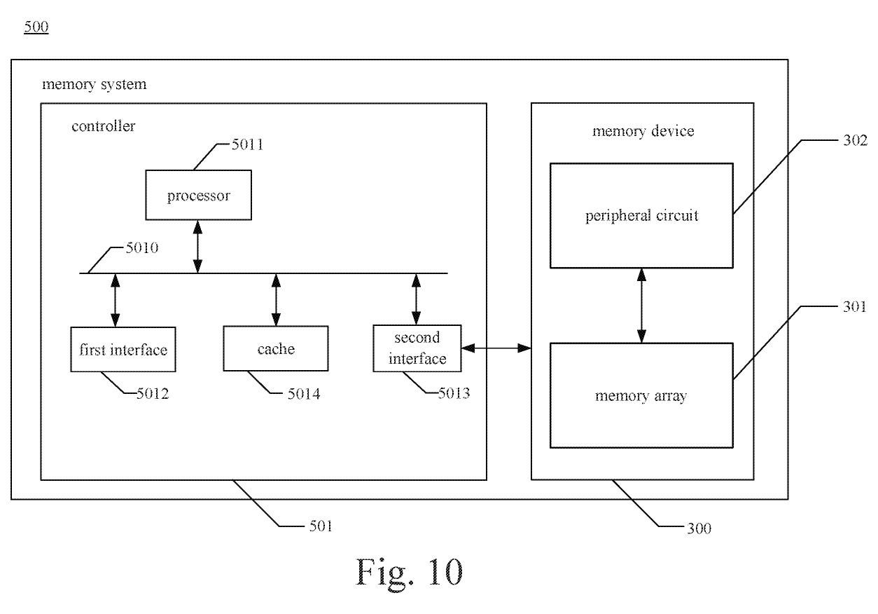

FIG. 10 is a schematic diagram of a memory system according to an example of the present disclosure. Referring to FIG. 10, the memory system 500 comprises a memory device 300 and a controller 501 coupled to the memory device 300. Here, the memory device 300 may be the memory device in any one of the above examples, comprising a memory array 301 and a peripheral circuit 302 coupled to the memory array.

In some examples, the controller 501 may comprise a processor 5011 and a first interface 5012, a second interface 5013, and a cache 5014 coupled to the processor 5011 through the bus 5010. The controller 501 may be coupled to the memory device 300 through the second interface 5013, and during data writing, the controller 501 may receive the write command, the write data, and the logical address of the write data through the first interface 5012, and may temporarily store the write data in the cache 5014, or may establish a mapping relationship between the logical address to physical address (L2P) for the write data, the controller 501 may send the program command to the memory device 300 via the second interface 5013, the memory device 300 may receive the program command and receive the write data and the physical address of the write data in response to the program command, and store the write data to the location in the memory array 301 corresponding to the physical address of the write data.

In some examples, the controller 501 is configured to: send a first detection command; the peripheral circuit 302 is configured to: perform a first detection operation in response to the first detection command, and send the first detection result to the controller 501; the controller 501 is further configured to: generate a second detection command based on the first detection result; and the peripheral circuit 302 is further configured to: perform the second detection operation in response to the second detection command.

In the example of the present disclosure, the memory device in the memory system may perform the first detection operation in response to the first detection command generated by the controller, and the peripheral circuit in the memory device may, after performing the first detection operation, record or update the detection state of each read phase in the first detection operation, and the controller may generate the second detection command based on the first detection result of the first detection operation, and the peripheral circuit may, before performing the second detection operation in response to the second detection command, obtain the detection states of the plurality of read phases in the first detection operation, and determine the number of read phases in the second detection operation based on the detection states of the plurality of read phases, for example, if the detection state of the first read phase in the first detection operation is the second state, the second detection operation may not comprise the second read phase corresponding to the first read phase, thereby shortening the time of the second detection operation and improving the efficiency of the valley search operation, thereby improving the efficiency of performing the read operation by the memory system.

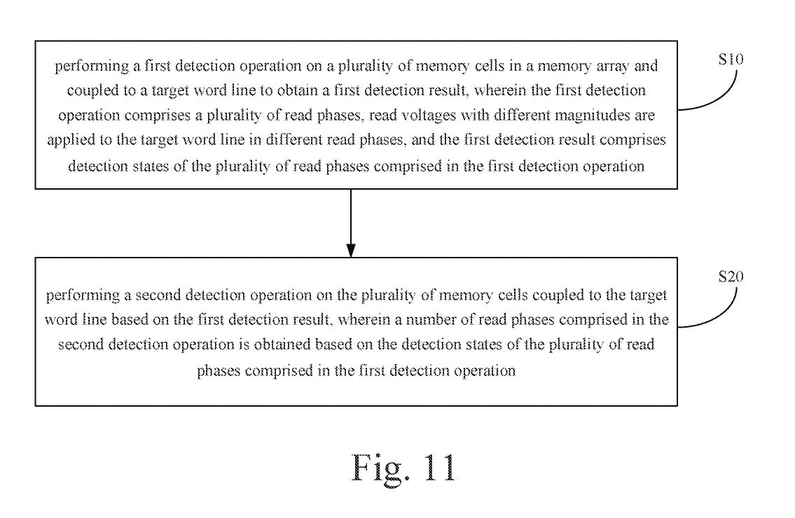

Based on a similar concept as the above memory device, the present disclosure further provides an operating method of a memory device, FIG. 11 is a schematic flowchart of an operating method of a memory device according to an example of the present disclosure, and the operating method of the memory device comprises the following operations:

Operation S10: performing a first detection operation on a plurality of memory cells in the memory array and coupled to a target word line to obtain a first detection result, wherein the first detection operation comprises a plurality of read phases, read voltages with different magnitudes are applied to the target word line in different read phases, and the first detection result comprises detection states of the plurality of read phases comprised in the first detection operation;

Operation S20: performing a second detection operation on the plurality of memory cells coupled to the target word line based on the first detection result; a number of the read phases comprised in the second detection operation is obtained based on the detection states of the plurality of read phases comprised in the first detection operation.

In some examples, the operating method of the memory device further comprises: performing N sensing operations in a first read phase, wherein the N sensing operations are performed at N different timings in the first read phase, respectively, the first read phase is one of the plurality of read phases comprised in the first detection operation and N is an integer greater than 1; and obtaining a detection state of the first read phase based on sensing results of the N sensing operations in the first read phase.

In some examples, the operating method of the memory device further comprises: obtaining a number of memory cells in a first memory state in the plurality of memory cells based on a sensing result of a sensing operation in the first read phase, wherein the sensing operation is any one of the N sensing operations, a threshold voltage of a memory cell in the first memory state is less than a compensation read voltage corresponding to a timing at which the sensing operation is performed, and the compensation read voltage is greater than or equal to a read voltage of the first read phase.

In some examples, the obtaining the detection state of the first read phase based on the sensing results of the N sensing operations in the first read phase comprises:

obtaining N-1 differences based on the sensing results of the N sensing operations in the first read phase, wherein any one of the N-1 differences is a difference between the numbers of memory cells in the first memory state obtained based on sensing results of two adjacent sensing operations in the N sensing operations, the first detection result further comprises a change trend of the N-1 differences, and N is an integer greater than 3; and obtaining the detection state of the first read phase based on the change trend of the N-1 differences.

In some examples, the operating method of the memory device further comprises: marking the detection state of the first read phase; wherein if the change trend of the N-1 differences is increasing or decreasing, the detection state of the first read phase is marked as a first state, and if the change trend of the N-1 differences is first decreasing and then increasing, the detection state of the first read phase is marked as a second state.

In some examples, a number of the read phases comprised in the second detection operation is a difference between a number of the read phases comprised in the first detection operation and a number of the read phases whose detection states are the second state in the plurality of read phases comprised in the first detection operation.

In some examples, the detection state of the first read phase is the first state; and the operating method of the memory device further comprises: obtaining a read voltage of a second read phase corresponding to the first read phase based on a read voltage of the first read phase and the change trend of the N-1 differences; and the second read phase is a read phase in the second detection operation.

In some examples, the detection state of the first read phase is the second state; and the operating method of the memory device further comprises: obtaining a read reference voltage corresponding to the first read phase based on the change trend of the N-1 differences in the first read phase and compensation read voltages corresponding to the timings at which the N sensing operations are performed; and the first detection result further comprises the read reference voltage.

In some examples, the operating method of the memory device comprises: performing a plurality of detection operations on the plurality of memory cells coupled to the target word line to obtain a plurality of read reference voltages, wherein the first detection operation and the second detection operation are two adjacent detection operations in the plurality of detection operations; and performing a read operation on the plurality of memory cells coupled to the target word line through the plurality of read reference voltages to obtain a page of data in M pages of data stored in the plurality of memory cells, wherein M is a positive integer.

The features disclosed in the several device examples according to the present disclosure may be arbitrarily combined without conflict, to obtain new device examples.

The methods disclosed in the several method examples according to the present disclosure may be arbitrarily combined without conflict, to obtain new method examples.

The above descriptions are only specific examples of the present disclosure, but the protection scope of the present disclosure is not limited thereto, and any variations or replacements within the technical scope of the present disclosure that can be easily conceived by those skilled in the art should be covered within the protection scope of the present disclosure.

What is claimed is:

1. A memory device, comprising:
a memory array; and
a peripheral circuit coupled to the memory array, wherein the peripheral circuit is configured to:
perform a first detection operation on a plurality of memory cells in the memory array and coupled to a target word line to obtain a first detection result, wherein the first detection operation comprises a plurality of read phases, read voltages with different magnitudes are applied to the target word line in different read phases, and the first detection result comprises detection states of the plurality of read phases comprised in the first detection operation; and
perform a second detection operation on the plurality of memory cells coupled to the target word line based on the first detection result, wherein a number of read phases comprised in the second detection operation is obtained based on the detection states of the plurality of read phases comprised in the first detection operation.

2. The memory device of claim 1, wherein the peripheral circuit is further configured to:
perform N sensing operations in a first read phase, wherein the N sensing operations are performed at N different timings in the first read phase, respectively, and the first read phase is one of the plurality of read phases comprised in the first detection operation, wherein N is an integer greater than 1; and
obtain a detection state of the first read phase based on sensing results of the N sensing operations in the first read phase.

3. The memory device of claim 2, wherein the peripheral circuit is configured to:
obtain a number of memory cells in a first memory state in the plurality of memory cells based on a sensing result of a sensing operation in the first read phase, wherein the sensing operation is any one of the N sensing operations, a threshold voltage of a memory cell in the first memory state is less than a compensation read voltage corresponding to a timing at which the sensing operation is performed; and the compensation read voltage is greater than or equal to a read voltage of the first read phase.

4. The memory device of claim 3, wherein N is an integer greater than 3; and the peripheral circuit is configured to:
obtain N-1 differences based on the sensing results of the N sensing operations in the first read phase, wherein any one of the N-1 differences is a difference between numbers of memory cells in the first memory state obtained based on sensing results of two adjacent sensing operations in the N sensing operations, and the first detection result further comprises a change trend of the N-1 differences; and
obtain the detection state of the first read phase based on the change trend of the N-1 differences.

5. The memory device of claim 4, wherein the peripheral circuit is further configured to:
mark the detection state of the first read phase, wherein if the change trend of the N-1 differences is increasing or decreasing, the detection state of the first read phase is marked as a first state, and if the change trend of the N-1 differences is first decreasing and then increasing, the detection state of the first read phase is marked as a second state.

6. The memory device of claim 5, wherein a number of read phases comprised in the second detection operation is a difference between a number of read phases comprised in the first detection operation and a number of read phases, whose detection states are the second state, in the plurality of read phases comprised in the first detection operation.

7. The memory device of claim 5, wherein the detection state of the first read phase is the first state, and the peripheral circuit is further configured to:
obtain a read voltage of a second read phase corresponding to the first read phase based on the read voltage of the first read phase and the change trend of the N-1 differences, wherein the second read phase is a read phase in the second detection operation.

8. The memory device of claim 5, wherein the detection state of the first read phase is the second state, and the peripheral circuit is further configured to:
obtain a read reference voltage corresponding to the first read phase based on the change trend of the N-1 differences in the first read phase and compensation read voltages corresponding to timings at which the N sensing operations are performed, wherein the first detection result further comprises the read reference voltage.

9. The memory device of claim 1, wherein the plurality of memory cells coupled to the target word line are configured to store M pages of data, M is a positive integer, and the peripheral circuit is configured to:
perform a plurality of detection operations on the plurality of memory cells coupled to the target word line to obtain a plurality of read reference voltages, wherein the first detection operation and the second detection operation are two adjacent detection operations in the plurality of detection operations; and
perform a read operation on the plurality of memory cells coupled to the target word line through the plurality of read reference voltages to obtain a page of data in the M pages of data.

10. A memory system, comprising:
at least one memory device comprising:
a memory array; and
a peripheral circuit coupled to the memory array, wherein the peripheral circuit is configured to:
perform a first detection operation on a plurality of memory cells in the memory array and coupled to a target word line to obtain a first detection result, wherein the first detection operation comprises a plurality of read phases, read voltages with different magnitudes are applied to the target word line in different read phases, and the first detection result comprises detection states of the plurality of read phases comprised in the first detection operation; and
perform a second detection operation on the plurality of memory cells coupled to the target word line based on the first detection result, wherein a number of read phases comprised in the second detection operation is obtained based on the detection states of the plurality of read phases comprised in the first detection operation; and
a controller coupled with the at least one memory device and configured to control the at least one memory device.

11. The memory system of claim 10, wherein the controller is configured to: send a first detection command;
the peripheral circuit is configured to: perform the first detection operation in response to the first detection command; and send the first detection result to the controller;
the controller is further configured to: generate a second detection command based on the first detection result; and
the peripheral circuit is further configured to: perform the second detection operation in response to the second detection command.

12. An operating method of a memory device, comprising:
performing a first detection operation on a plurality of memory cells in a memory array and coupled to a target word line to obtain a first detection result, wherein the first detection operation comprises a plurality of read phases, read voltages with different magnitudes are applied to the target word line in different read phases, and the first detection result comprises detection states of the plurality of read phases comprised in the first detection operation; and
performing a second detection operation on the plurality of memory cells coupled to the target word line based on the first detection result, wherein a number of read phases comprised in the second detection operation is obtained based on the detection states of the plurality of read phases comprised in the first detection operation.

13. The operating method of the memory device of claim 12, further comprising:
performing N sensing operations in a first read phase, wherein the N sensing operations are performed at N different timings in the first read phase, respectively, the first read phase is one of the plurality of read phases comprised in the first detection operation, and N is an integer greater than 1; and
obtaining a detection state of the first read phase based on sensing results of the N sensing operations in the first read phase.

14. The operating method of the memory device of claim 13, further comprising:
obtaining a number of memory cells in a first memory state in the plurality of memory cells based on a sensing result of a sensing operation in the first read phase, wherein the sensing operation is any one of the N sensing operations, a threshold voltage of a memory cell in the first memory state is less than a compensation read voltage corresponding to a timing at which the sensing operation is performed, and the compensation read voltage is greater than or equal to a read voltage of the first read phase.

15. The operating method of the memory device of claim 14, wherein obtaining the detection state of the first read phase based on the sensing results of the N sensing operations in the first read phase comprises:
obtaining N-1 differences based on the sensing results of the N sensing operations in the first read phase, wherein any one of the N-1 differences is a difference between numbers of memory cells in the first memory state obtained based on sensing results of two adjacent sensing operations in the N sensing operations, the first detection result further comprises a change trend of the N-1 differences, and N is an integer greater than 3; and
obtaining the detection state of the first read phase based on the change trend of the N-1 differences.

16. The operating method of the memory device of claim 15, further comprising:
marking the detection state of the first read phase, wherein if the change trend of the N-1 differences is increasing or decreasing, the detection state of the first read phase is marked as a first state, and if the change trend of the N-1 differences is first decreasing and then increasing, the detection state of the first read phase is marked as a second state.

17. The operating method of the memory device of claim 16, wherein a number of read phases comprised in the second detection operation is a difference between a number of read phases comprised in the first detection operation and a number of read phases, whose detection states are the second state, in the plurality of read phases comprised in the first detection operation.

18. The operating method of the memory device of claim 16, wherein the detection state of the first read phase is the first state, and the operating method further comprises:
obtaining a read voltage of a second read phase corresponding to the first read phase based on a read voltage of the first read phase and the change trend of the N-1 differences, wherein the second read phase is a read phase in the second detection operation.

19. The operating method of the memory device of claim 16, wherein the detection state of the first read phase is the second state, and the operating method further comprises:
obtaining a read reference voltage corresponding to the first read phase based on the change trend of the N-1 differences in the first read phase and compensation read voltages corresponding to timings at which the N sensing operations are performed, wherein the first detection result further comprises the read reference voltage.

20. The operating method of the memory device of claim 12, further comprising:
performing a plurality of detection operations on the plurality of memory cells coupled to the target word line to obtain a plurality of read reference voltages, wherein the first detection operation and the second detection operation are two adjacent detection operations in the plurality of detection operations; and
performing a read operation on the plurality of memory cells coupled to the target word line through the plurality of read reference voltages to obtain a page of data in M pages of data stored in the plurality of memory cells, wherein M is a positive integer.
